(19) United States
(12) Patent Application Publication
(10) Pub. No.: US 2013/0114059 A1
(43) Pub. Date: May 9, 2013

(54) Components for EUV Lithographic Apparatus, EUV Lithographic Apparatus Including Such Components and Method for Manufacturing Such Components

(71) Applicants: Martin Jacobus Johan Jak, Eindhoven (NL); Vadim Yevgenyevich Banine, Deurne (NL); Wouter Anthon Soer, Nijmegen (NL); Andrei Mikhailovich Yakunn, Eindhoven (NL); Maarten Van Kampen, Eindhoven (NL); Gerard Frans Jozef Schasfoort, Eindhoven (NL)

(72) Inventors: Martin Jacobus Johan Jak, Eindhoven (NL); Vadim Yevgenyevich Banine, Deurne (NL); Wouter Anthon Soer, Nijmegen (NL); Andrei Mikhailovich Yakunn, Eindhoven (NL); Maarten Van Kampen, Eindhoven (NL); Gerard Frans Jozef Schasfoort, Eindhoven (NL)

(73) Assignee: ASML Netherlands B.V., Veldhoven (NL)

(21) Appl. No.: 13/808,636

(22) PCT Filed: Jun. 6, 2011
(86) PCT No.: PCT/EP2011/059303

§ 371 Date: Jan. 7, 2013

Related U.S. Application Data
(60) Provisional application No. 61/361,751, filed on Jul. 6, 2010.

(51) Int. Cl. C09D 5/08; B32B 15/01; G02B 5/20; G03F 7/20

(52) U.S. Cl. CPC C09D 5/08; G03F 7/70858; B32B 15/01; B32B 15/018; G02B 5/208
USPC 355/67; 428/457; 428/656; 428/469; 428/472; 428/686; 428/650; 428/660; 359/350

(57) ABSTRACT

A metal component (262M, 300M) is designed for use in an EUV lithography apparatus, for example as a spectral purity filter (260) or a heating element (300) in a hydrogen radical generator. An exposed surface of the metal is treated (262P, 300P) to inhibit the formation of an oxide of said metal in an air environment prior to operation. This prevents contamination of optical components by subsequent evaporation of the oxide during operation of the component at elevated temperatures.

### CROSS-REFERENCE TO RELATED APPLICATIONS

This application claims the benefit of U.S. provisional application 61/361,751, which was filed on Jul. 6, 2011, and which is incorporated herein in its entirety by reference

FIELD

The present invention relates to metal components for use at elevated temperatures inside extreme ultraviolet (EUV) lithographic apparatus. Such components may be for example metal grid type spectral purity filters and filament type hydrogen radical generators, but the invention is not limited to these. The invention further relates to lithographic apparatus including such components, and methods for manufacturing such components.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., including part of one or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include steppers, in which each target portion is irradiated by exposing an entire pattern onto the target portion at one time, and scanners, in which each target portion is irradiated by scanning the pattern through a radiation beam in a given direction (the “scanning” direction) while synchronously scanning the substrate parallel or anti parallel to this direction. It is also possible to transfer the pattern from the patterning device to the substrate by imprinting the pattern onto the substrate.

A key factor limiting pattern printing is the wavelength of the radiation used. In order to be able to project ever smaller structures onto substrates, it has been proposed to use extreme ultraviolet (EUV) radiation which is electromagnetic radiation having a wavelength within the range of 10-20 nm, for example within the range of 13-14 nm. It has further been proposed that EUV radiation with a wavelength of less than 10 nm could be used, for example within the range of 5-10 nm such as 6.7 nm or 6.8 nm. Such EUV radiation is sometimes termed soft x-ray. Possible sources include, for example, laser-produced plasma sources, discharge plasma sources, or synchrotron radiation from electron storage rings.

EUV sources based on a Sn plasma do not only emit the desired in-band EUV radiation but also out-of-band radiation, most notably in the deep UV (DUV) range (100-400 nm). Moreover, in the case of Laser Produced Plasma (LPP) EUV sources, the infrared radiation from the laser, usually at 10.6 μm, presents a significant amount of unwanted radiation. Since the optics of the EUV lithographic system generally have substantial reflectivity at these wavelengths, the unwanted radiation propagates into the lithography tool with significant power if no measures are taken.

In a lithographic apparatus, out-of-band radiation should be minimized for several reasons. Firstly, resist is sensitive to out-of-band wavelengths, and thus the image quality may be deteriorated. Secondly, unwanted radiation, especially the 10.6 μm radiation in LPP sources, leads to unwanted heating of the mask, wafer and optics. In order to bring unwanted radiation within specified limits, spectral purity filters (SPFs) are being developed.

Spectral purity filters can be either reflective or transmissive for EUV radiation.

Grid SPFs form a class of transmissive SPFs that may be used when the unwanted radiation has a much larger wavelength than the EUV radiation, for example in the case of 10.6 μm radiation in LPP sources. Grid SPFs contain apertures with a size of the order of the wavelength to be suppressed. The suppression mechanism may vary among different types of grid SPFs as described in the prior art and detailed embodiments further in this document. Since the wavelength of EUV radiation (13.5 nm) is much smaller than the size of the apertures (typically >3 μm), EUV radiation is transmitted through the apertures without substantial diffraction.

Several known spectral purity filters (SPFs) rely on a grid with micron-sized apertures to suppress unwanted radiation. U.S. Patent Application Publication 2006/0146413 discloses a spectral purity filter (SPF) comprising an array of apertures with diameters up to 20 μm. Depending on the size of the apertures compared to the radiation wavelength, the SPF may suppress unwanted radiation by different mechanisms. If the aperture size is smaller than approximately half of the (unwanted) wavelength, the SPF reflects virtually all radiation of this wavelength. If the aperture size is larger, but still of the order of the wavelength, the radiation is at least partially diffracted and may be absorbed in a waveguide inside the aperture.

The approximate material parameters and specifications for these SPFs are known. However, manufacturing is not straightforward at these specifications. The most challenging specifications are: apertures of typically 4-5 μm in diameter; a grid thickness of typically 5-10 μm; very thin (typically <1 μm) and parallel (non-tapered) walls between the apertures to ensure maximal EUV transmission.

Silicon has been proposed as a promising material for the manufacture of such grids, using the photolithographic patterning and anisotropic etching processes that are well-understood from semiconductor manufacturing Also, silicon grid SPFs may be coated with a metal layer to improve reflectivity of unwanted radiation. In either case, grid SPFs are a type of metal or partly metal component that may be deployed and operated at high temperatures in an EUV lithographic apparatus.

Another example of a metal component that is proposed for operation operated at an elevated temperature in EUV apparatus is a hydrogen radical generator (HRG). It is well known that EUV-irradiated surfaces including the optical mirrors can become contaminated during use. Sources of contamination include the EUV source itself, and outgassing of hydrocarbons from components and resist materials. To prevent unacceptable transmission loss of the optical column, and thus throughput loss, of the lithographic apparatus, this contamination needs to be cleaned away on a regular basis. As one measure, it is planned to use in-situ atomic hydrogen cleaning to remove carbon deposits from the mirrors. A hydrogen gas flow from the generators then transports the atomic hydrogen towards the contaminated surfaces, where it reacts with carbon and forms volatile hydrocarbons (CH4 and others) that can be pumped away. Filament HRGs are considered as one means to atomize molecular hydrogen for this purpose. This HRG comprises a metal filament heated by electric current to high temperatures, for example in the range 1700 to 1900 Celsius.

A problem arises with metal components such as these metal grid SPFs and filament HRGs, in that they can themselves become a source of contamination. Using tungsten as an example, after exposure of the component to oxygen gas (or other oxidants), a thin layer of tungsten oxide (WOx) will form on the surface. This WOx layer can and will evaporate when the filament is heated to operating temperature without precautions. This evaporated WOx will then deposit on surfaces nearby, including EUV mirrors and sensors, and causes reflection losses.

While the components in use are operated in a vacuum vessel containing a controlled, near-vacuum, non-oxidizing atmosphere, air exposure of filaments cannot be prevented during system manufacture and transport. Even after the apparatus is fully commissioned and operational, occasional servicing operations will require venting operations, which re-introduce air to the environment of the components.

### SUMMARY

According to a first aspect of the present invention, there is provided a component for use in an EUV lithography apparatus, the component being made at least partly of a metal and in use being located in a near-vacuum environment and being operated at an elevated temperature relative to the environment, wherein an exposed surface of the metal has been treated to inhibit the formation of an oxide of said metal in an air environment prior to operation, thereby to prevent contamination of said environment by subsequent evaporation of said oxide during operation at said elevated temperature.

According to a further aspect of the present invention, there is provided a lithographic apparatus that includes a radiation source configured to generate radiation comprising extreme ultraviolet radiation, an illumination system configured to condition the radiation into a beam of radiation, and a support configured to support a patterning device. The patterning device is configured to pattern the beam of radiation. The apparatus also includes a projection system configured to project a patterned beam of radiation onto a target material. At least one of said radiation source, said illumination system and said projection system is housed in a near-vacuum environment with a component according to the invention as set forth above.

According to a further aspect of the present invention there is provided a method for manufacturing a component according to the invention as set forth above.

According to an aspect of the present invention a component for use in an EUV lithography apparatus is provided. The component may include a metal, wherein the metal is configured to be located in a near-vacuum environment and operated at an elevated temperature relative to the environment, wherein an exposed surface of the metal comprises a treatment to inhibit the formation of an oxide of the metal in an air environment prior to operation, thereby to prevent contamination of said environment by subsequent evaporation of said oxide during operation at said elevated temperature.

The metal may include Tungsten, an alloy of Tungsten, Molybdenum or an alloy of Molybdenum. The metal may include a coating of a different material, the different material not forming an oxide volatile at said elevated temperature. The different material may be less susceptible to oxidation than the metal, and said different metal comprising at least one of Iridium, Rhenium, Rhodium, Ruthenium and Platinum. The different material may include an oxide more stable than an oxide of the metal itself, and comprises at least one of aluminium oxide, zirconium oxide and hafnium oxide. The different material optionally includes at least one of a nitride, a carbide, diamond-like carbon and a metal silicide. The metal may have a layer of a different material formed by a treatment at the exposed surface of said metal. The different material may contain a nitride or a carbide of the metal. The metal may include an alloy in which at least one constituent segregates at the surface, thereby changing composition of the metal at the exposed surface. The constituent may be a different metal less susceptible to oxidation than the metal, the different metal comprising at least one of iridium, Rhenium, Rhodium, Ruthenium and Platinum. The constituent may be a different metal whose oxide is less susceptible to evaporation than said metal, the different metal optionally including at least one of aluminium, zirconium oxide and hafnium.

The component may have the form of a spectral purity filter configured to transmit extreme ultraviolet radiation, the spectral purity filter comprising a filter part having a plurality of apertures to transmit extreme ultraviolet radiation and to suppress transmission of a second type of radiation, the filter part being fabricated in said metal or fabricated in a carrier material and coated at least partially with said metal.

The component may have the form of a heating element for heating gaseous molecules in said environment for the generation of atomic gas, such as atomic hydrogen.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts schematically a lithographic apparatus according to an embodiment of the invention;

FIG. 2 is a more detailed view of the apparatus 100 according to an embodiment of the invention;

FIG. 3 illustrates an alternative EUV radiation source usable in the apparatus of FIGS. 1 and 2 according to an embodiment of the invention;

FIG. 4 illustrates a modified lithographic apparatus also in accordance with an embodiment of the invention;

FIG. 5(a) is a schematic front view and FIG. 5(b) is a schematic cross-section of a grid type spectral purity filter useful in an EUV lithographic apparatus;

FIGS. 6 and 7 are schematic cross sections of spectral purity filter parts modified in accordance with embodiments of the present invention;

FIG. 8 is a schematic view of a filament type hydrogen radical generator useful in the apparatus of FIGS. 1 to 4; and

FIG. 9 is a schematic view of a filament type hydrogen radical generator modified in accordance with embodiments of the present invention.

### DETAILED DESCRIPTION

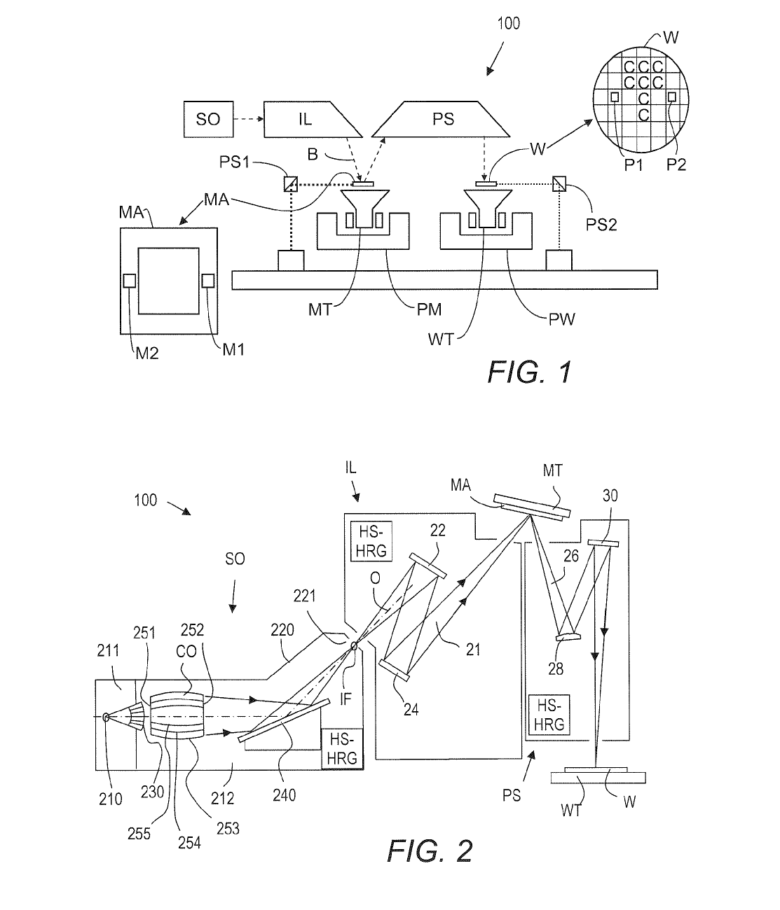

FIG. 1 schematically depicts a lithographic apparatus 100 including a source collector module SO according to one embodiment of the invention. The apparatus includes:
an illumination system (illuminator) IL configured to condition a radiation beam B (e.g., EUV radiation).
a patterning device support or support structure (e.g., a mask table) MT constructed to support a patterning device (e.g., a mask or a reticle) MA and connected to a first positioner PM configured to accurately position the patterning device;
a substrate table (e.g., a wafer table) WT constructed to hold a substrate (e.g., a resist coated wafer) W and connected to a second positioner PW configured to accurately position the substrate; and
a projection system (e.g., a reflective projection system) PS configured to project a pattern imparted to the radiation beam B by patterning device MA onto a target portion C (e.g., including one or more dies) of the substrate W.

The illumination system may include various types of optical components, such as refractive, reflective, magnetic, electromagnetic, electrostatic or other types of optical components, or any combination thereof, to direct, shape, or control radiation.

The patterning device support MT holds the patterning device MA in a manner that depends on the orientation of the patterning device, the design of the lithographic apparatus, and other conditions, such as for example whether or not the patterning device is held in a vacuum environment. The patterning device support can use mechanical, vacuum, electrostatic or other clamping techniques to hold the patterning device. The patterning device support may be a frame or a table, for example, which may be fixed or movable as required. The patterning device support may ensure that the patterning device is at a desired position, for example with respect to the projection system.

The term “patterning device” should be broadly interpreted as referring to any device that can be used to impart a radiation beam with a pattern in its cross-section such as to create a pattern in a target portion of the substrate. The pattern imparted to the radiation beam may correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The projection system, like the illumination system, may include various types of optical components, such as refractive, reflective, magnetic, electromagnetic, electrostatic or other types of optical components, or any combination thereof, as appropriate for the exposure radiation being used, or for other factors such as the use of a vacuum. It may be desired to use a vacuum for EUV radiation since other gases may absorb too much radiation. A vacuum environment may therefore be provided to the whole beam path with the aid of a vacuum wall and vacuum pumps.

As here depicted, the apparatus is of a reflective type (e.g., employing a reflective mask).

The lithographic apparatus may be of a type having two (dual stage) or more substrate tables (and/or two or more mask tables). In such “multiple stage” machines the additional tables may be used in parallel, or preparatory steps may be carried out on one or more tables while one or more other tables are being used for exposure.

Referring to FIG. 1, the illuminator IL receives an extreme ultra violet radiation beam from the source collector module SO. Methods to produce EUV light include, but are not necessarily limited to, converting a material into a plasma state that has at least one element, e.g., xenon, lithium or tin, with one or more emission lines in the EUV range. In one such method, often termed laser produced plasma (“LPP”) the required plasma can be produced by irradiating a fuel, such as a droplet, stream or cluster of material having the required line-emitting element, with a laser beam. The source collector module SO may be part of an EUV radiation system including a laser, not shown in FIG. 1, for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser is not considered to form part of the lithographic apparatus and the radiation beam is passed from the laser to the source collector module with the aid of a beam delivery system including, for example, suitable directing mirrors and/or a beam expander. In other cases the source may be an integral part of the source collector module, for example when the source is a discharge produced plasma EUV generator, often termed as a DPP source.

The illuminator IL may include an adjuster to adjust the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may include various other components, such as facetted field and pupil mirror devices. The illuminator may be used to condition the radiation beam, to have a desired uniformity and intensity distribution in its cross section.

The radiation beam B is incident on the patterning device (e.g., mask) MA, which is held on the patterning device support (e.g., mask table) MT, and is patterned by the patterning device. After being reflected from the patterning device (e.g., mask) MA, the radiation beam B passes through the projection system PS, which focuses the beam onto a target portion C of the substrate W. With the aid of the second positioner PW and position sensor PS2 (e.g., an interferometric device, linear encoder or capacitive sensor), the substrate table WT can be moved accurately, e.g., so as to position different target portions C in the path of the radiation beam B. Similarly, the first positioner PM and another position sensor PS1 can be used to accurately position the patterning device (e.g., mask) MA with respect to the path of the radiation beam B. Patterning device (e.g., mask) MA and substrate W may be aligned using mask alignment marks M1, M2 and substrate alignment marks P1, P2.

The depicted apparatus could be used in at least one of the following modes:

1. In step mode, the patterning device support (e.g., mask table) MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed.

2. In scan mode, the patterning device support (e.g., mask table) MT and the substrate table WT are scanned synchronously while a pattern imparted to the radiation beam is projected onto a target portion C (i.e. a single dynamic exposure). The velocity and direction of the substrate table WT relative to the patterning device support (e.g., mask table) MT may be determined by the (de-)magnification and image reversal characteristics of the projection system PS.

3. In another mode, the patterning device support (e.g., mask table) MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

FIG. 2 shows the apparatus 100 in more detail, including the source collector module SO, the illumination system IL, and the projection system PS. The source collector module SO is constructed and arranged such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the very hot plasma 210 is created to emit radiation in the EUV range of the electromagnetic spectrum. The very hot plasma 210 is created by, for example, an electrical discharge causing an at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contaminant trap 230 may also include a gas barrier or a combination of a gas barrier and a channel structure. The contaminant trap or contaminant barrier 230 further indicated herein at least includes a channel structure, as known in the art.

The collector chamber 211 may include a radiation collector CO which may be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point IF. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the beam of radiation 21 at the patterning device MA, held by the patterning device support MT, a patterned beam 26 is formed and the patterned beam 26 is imaged by the projection system PS via reflective elements 28, 30 onto a substrate W held by the wafer stage or substrate table WT.

More elements than shown may generally be present in illumination optics unit IL and projection system PS. The grating spectral filter 240 may optionally be present, depending upon the type of lithographic apparatus. Further, there may be more mirrors present than those shown in the Figures, for example there may be 1-6 additional reflective elements present in the projection system PS than shown in FIG. 2.

Collector optic CO, as illustrated in FIG. 2, is depicted as a nested collector with grazing incidence reflectors 253, 254 and 255, just as an example of a collector (or collector mirror). The grazing incidence reflectors 253, 254 and 255 are disposed axially symmetric around an optical axis O and a collector optic CO of this type is preferably used in combination with a discharge produced plasma source, often called a DPP source.

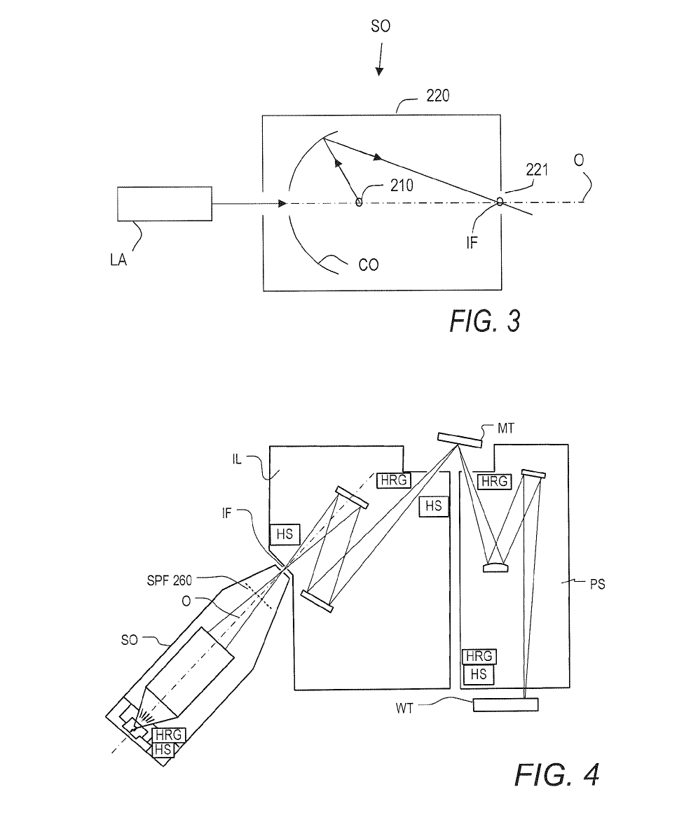

Alternatively, the source collector module SO may be part of an LPP radiation system as shown in FIG. 3. A laser LA is arranged to deposit laser energy into a fuel, such as xenon (Xe), tin (Sn) or lithium (Li), creating the highly ionized plasma 210 with electron temperatures of several 10's of eV. The energetic radiation generated during de-excitation and recombination of these ions is emitted from the plasma, collected by a near normal incidence collector optic CO and focused onto the opening 221 in the enclosing structure 220.

FIG. 4 shows an alternative arrangement for an EUV lithographic apparatus in which the spectral purity filter (SPF) 260 is of a transmissive type, rather than a reflective grating. The radiation from source collector module SO in this case follows a straight path from the collector to the intermediate focus IF (virtual source point). In alternative embodiments, not shown, the spectral purity filter 260 may be positioned at the virtual source point 12 or at any point between the collector 10 and the virtual source point 12. The filter can be placed at other locations in the radiation path, for example downstream of the virtual source point 12. Multiple filters can be deployed. As in the previous examples, the collector CO may be of the grazing incidence type (FIG. 2) or of the direct reflector type (FIG. 3).

As mentioned above, a contaminant trap 230 including a gas bather is provided in the source compartment. The gas barrier includes a channel structure such as, for instance, described in detail in U.S. Pat. No. 6,614,505 and U.S. Pat. No. 6,359,969, which are incorporated herein by reference. The purpose of this contaminant trap is to prevent or at least reduce the incidence of fuel material or by-products impinging on the elements of the optical system and degrading their performance over time. The gas barrier may act as a physical bather (by fluid counter-flow), by chemical interaction with contaminants and/or by electrostatic or electromagnetic deflection of charged particles. In practice, a combination of these methods are employed to permit transfer of the radiation into the illumination system, while blocking the plasma material to the greatest extent possible. Hydrogen or other gas may be provided as a barrier or buffer against contaminant particles at other points in the lithographic apparatus. In particular, a flow of hydrogen into the near-vacuum environment of source collector module SO can be arranged, to impede particles that may try to pass through the intermediate focus aperture 221 into the projection system. Further, hydrogen gas may be deployed (i) in the vicinity of the patterning device (e.g., reticle) support MT, as a buffer against contaminants from the system contaminating the reticle and (ii) in the vicinity of the wafer support WT, as a buffer against contaminants from the wafer entering the larger vacuum spaces within the system. Hydrogen is not the only gas that may be used in the EUV optics environment. Helium is known as another gas that can be used in a contaminant trap.

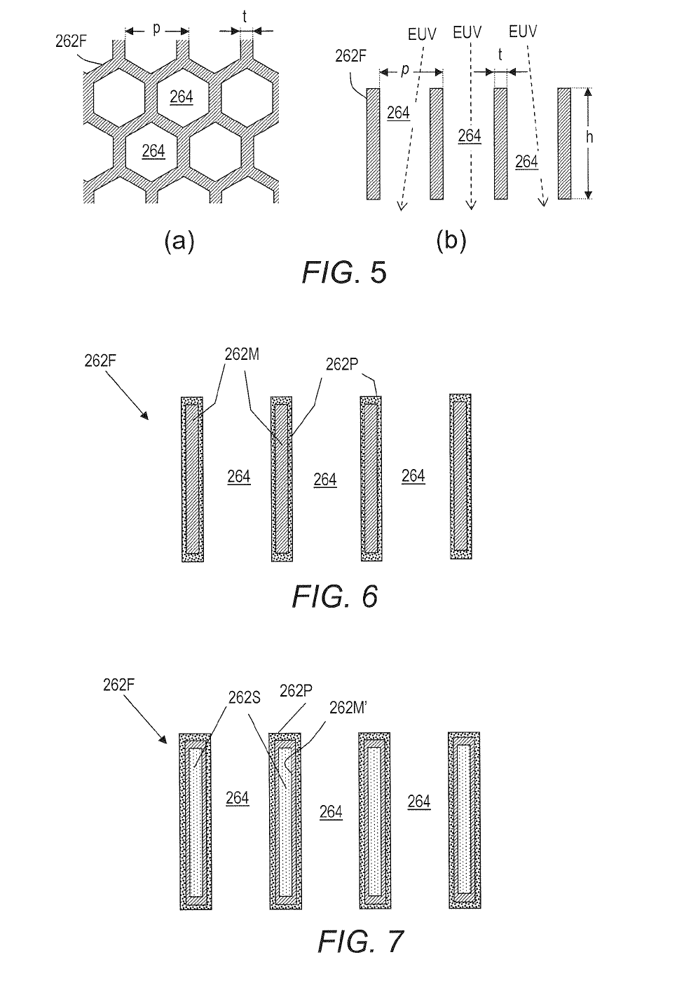

For all these purposes, hydrogen sources HS and hydrogen radical generators HRG are deployed at various points in the apparatus (some shown schematically, some not shown). Sources HS supply molecular hydrogen gas (H2) as a simple buffer or ‘gas lock’. Hydrogen radical generators HRG generate atomic hydrogen (H) for more active cleaning of specific optical components, including mirrors, the spectral purity filter (see below) and sensor surfaces. Some units may serve both functions at the same time, or at different times. For carbon-based contamination, a hydrogen gas flow from the generators then transports the atomic hydrogen towards the contaminated surfaces, where it reacts with carbon and forms volatile hydrocarbons (CH4 and others) that can be pumped away. FIG. 5 (a) is a schematic front face view of part of an embodiment of a spectral purity filter grid, while FIG. 5 (b) is a cross-section of the same grid. The grid may for example be applied as an above-mentioned filter 260 of a lithographic apparatus. The present filter is configured to transmit extreme ultraviolet (EUV) radiation, but substantially blocks a second type of radiation generated by a radiation source, for example infrared (IR) radiation, for example infrared radiation of a wavelength larger than about 1 μm, particularly larger than about 10 μm. Particularly, the EUV radiation to be transmitted and the second type of radiation (to be blocked) can emanate from the same radiation source, for example an LPP source of a lithographic apparatus.

The spectral purity filter 100 in the examples to be described comprises a substantially planar filter part 262F (for example a filter film or filter layer). The filter part 262F as such can be called a ‘filter substrate’. The filter part 262F has a plurality of (preferably parallel) apertures 264 to transmit the extreme ultraviolet radiation and to suppress transmission of the second type of radiation. The face on which radiation impinges from the source SO will be referred to as the front face, while the face from which radiation exits to the illumination system IL can be referred to as the rear face. As is mentioned above, for example, the EUV radiation can be transmitted by the spectral purity filter without changing the direction of the radiation. In a first preferred embodiment each aperture 264 has parallel sidewalls defining the apertures and extending completely from the front to the rear face.

An embodiment of the filter manufacturing method comprises depositing a film of metal on a substrate and then applying anisotropic etching similar to that used in the production of silicon grid SPFs. The photolithographic patterning and anisotropic etching processes are well-understood from semiconductor manufacturing. For deep apertures with a well-controlled cross-section, deep reactive ion etching (DRIE) has been found promising. U.S. application No. 61/193,769 filed on 22 Dec. 2008 discloses various methods for manufacture that are applicable in the production of silicon grid SPFs and can be adapted for metal grid SPFs also. The content of that application are incorporated herein by reference.

Under typical operating conditions, a large amount of power is incident on the SPF, and therefore it may become very hot. While silicon is a promising material for the manufacture of SPFs, consideration is also given to grids manufactured of refractory metal or alloy, that can withstand higher operating temperatures than silicon. U.S. application No. 61/328,426 filed on 27 Apr. 2010, for example, discloses a grid SPF based on a refractory metal or alloy, for example tungsten (W) or molybdenum (Mo). The contents of that application are incorporated herein by reference.

The (close packed) hexagonal structure of the walls of the filter part 262F provides a very durable and open configuration, but is not the only possible configuration. Advantageously, EUV radiation is directly transmitted through the apertures 104, preferably utilizing a relatively thin filter 260, in order to keep the aspect ratio of the apertures low enough to allow EUV transmission with a significant angular spread. Thickness h of the filter part 262F (i.e. the length of each of the apertures 264) is for example smaller than 20 μm, for example in the range of 2-10 μm. Also, each of the apertures 264 may have a diameter in the range of about 1.5-6 μm, for example the range of 2-5 μm. Thickness t of the walls between the filter apertures 264 may be smaller than 1 μm, for example in the range of about 0.2-0.6 μm, particularly about 0.5 μm. The apertures 264 may have a period p of in the range of about 2 to 6 μm, particularly 3 to 5 μm, for example 5 μm. Consequently, the apertures may provide an open area of about 70-80% of a total filter front surface.

Advantageously, the filter 100 is configured to provide at most 5% infrared light (IR) transmission. Also, advantageously, the filter 100 is configured to transmit at least 60% of incoming EUV radiation at a normal incidence. Besides, particularly, the filter 100 can provide at least 40% of transmission of EUV radiation having an angle of incidence (with respect of a normal direction) of 10°. As explained in the introduction, SPF grid parts made of silicon have been proposed. Optionally they may be coated with metal to improve IR reflectivity. The grid part 262F of the present example is made entirely of a refractory metal or alloy, so as to withstand higher operating temperature than a silicon-based SPF. However, the invention may also be applied to a metal coating on a silicon grid. The refractory metal that the grid is made of, or the metallic coating that is used on a silicon grid needs to have a good IR reflectivity (most metals do), and should be stable at high temperatures and in hydrogen. Therefore both molybdenum and tungsten are suitable candidates. However, both materials form a thin oxide layer when exposed to air. During operation the filter can reach very high temperatures, even 1000 Celsius. At those temperatures the oxides become volatile, and desorb from the filter. The desorbed material may condense on the cooler parts of the system, such as the mirrors shown in FIGS. 2, 3 and 4. This will reduce the reflectivity and lifetime of these mirrors, and hence reduce the productivity of the expensive lithographic apparatus. It is not practical to manufacture and install the SPF without exposing it to air.

Although the oxide layer is likely to be quite thin (about 1 nm), and thus the amount of desorbed material small, it may re-grow every time the system is vented for servicing. This makes it potentially a very serious problem. Additionally the amount of deposited material that can be tolerated on the mirrors is extremely small. Fractions of a monolayer of contamination may be sufficient to degrade performance significantly. We propose to add a thin coating to the grid or to modify the surface of the grid in such a way that the formation of volatile oxides is prevented. When these oxides are not formed, they cannot desorb. The coating should be able to withstand both the operating temperature and the hydrogen atmosphere in the EUV apparatus.

FIG. 6 illustrates a modified grid part 262F in which the metal part 262M is coated with a protective coating 262P. FIG. 7 illustrates a silicon-based grid structure in which a silicon grid part 262S is coated first with a reflective metal layer 262M′ and the metal surface in turn is covered with a protective coating 262P. The relative thicknesses of these layers are very much not to scale: the layer 262M′ and coating 262P are shown with exaggerated thickness for the sake of illustration only.

Several types of coating 262P can be used to prevent oxidation of for example the tungsten grid material. In a first series of embodiments the coating comprises a noble metal layer that does not form oxides. As it should also be stable at high temperatures, it should preferably also have a high melting point. Therefore the coating may be made of Iridium, Rhenium, Rhodium, Ruthenium or Platinum. Advantageously, these coatings are also expected to have a good IR reflectivity and able to withstand the hydrogen atmosphere.

In a second series of embodiments the coating 262P comprises or forms a very stable oxide that does not become volatile, even at operating conditions. Possible oxides include aluminum oxide, zirconium oxide and hafnium oxide. In further series of embodiments nitrides or carbides (e.g., SiC) are another possibility and so are Diamond-like carbon, and various metal silicides (e.g., MoSi2).

An additional benefit of an oxide coating like e.g., HfO2 may be that it can slow down the surface diffusion of tungsten, and thus prevent or reduce lifetime issues due to recrystallization. (See, for example, Schlemmer et al., Proc of the 5th conference on ThermoPhotovoltaic Generation of Electricity, p. 164 (2003)).

Instead of depositing a foreign material on the grid, a surface of the grid (metal part 262M or metal layer 262M′) may also be modified in order to prevent volatile oxides to form. The material may be modified by nitridation or carbidization for example. Alternatively an alloy may be used with an element that tends to segregate to the surface, in which the element either is a noble metal (as in the first series or embodiments), or forms a stable oxide (as in the second series of embodiments). As an example Hf may segregate to the surface in a W—Hf alloy.(See, for example, Golubev et al., Technical Physics 48, 776-779 (2003), see also at http://www.springerlink.com/index/15L4201812058521.pdf.

In order to maintain the open area fraction of the grid, and thus EUV transmission, the coating 262P should be sufficiently thin. This is especially true for the oxide and other non-metallic coatings, as thick layers may lead to an increase in absorption of infrared, and thus a rise in temperature. Furthermore the coating should preferably cover the grid walls all around and not contain any holes. A IR reflecting metal coating should preferably be <100 nm thick, while a non-reflecting coating should preferably be <20 nm thick.

The coating may be deposited by several techniques such as PVD (physical vapor deposition), sputter deposition, CVD (chemical vapor deposition) or ALD (atomic layer deposition). Most preferably CVD or ALD is used as it is expected to give the best sidewall coverage. ALD uses alternating steps of a self-limiting surface reaction to deposit atomic layers one by one. The material to be deposited is provided through a precursor. ALD methods are known for several metals, for example, Mo, Ti, Ru, Pd, Ir, Pt, Rh, Co, Cu, Fe and Ni. Compound materials such as the oxides mentioned above may be deposited at once, or they may be deposited as a metal film (e.g., aluminum) and oxidized later.

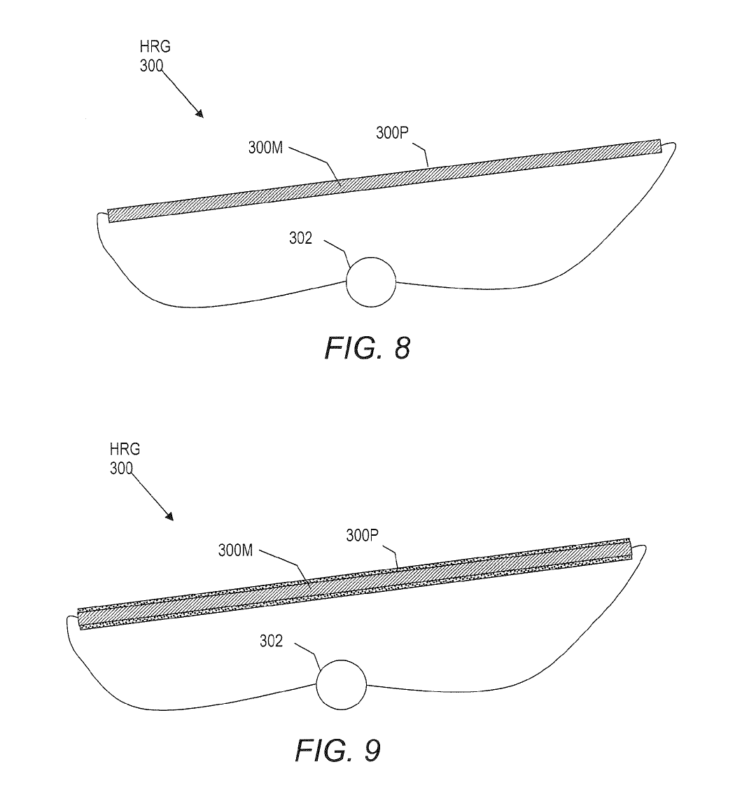

FIG. 8 shows in schematic form a hydrogen radical generator HRG 300 comprising a heating element in the form of a metal filament (wire) 300M. By heating the filament using electric current from a power source 302, the filament is raised to a temperature sufficient to disassociate hydrogen molecules and form atomic hydrogen. This temperature may for example be 1700 to 1900 Celsius, or higher if the filament material does not evaporate. Such an HRG can be deployed at several locations in the lithographic apparatus, as shown in FIGS. 2 and 4. A hydrogen gas flow from the generators then transports the atomic hydrogen towards contaminated surfaces, where it reacts with carbon and forms volatile hydrocarbons (CH4 and others) that can be pumped away. In practice, of course, there may be more than one filament in the heating element of HRG 300 and the shape of the filaments may be convoluted and/or made into a grid. Metal heating elements of different forms may be used instead of or in addition to filaments, and the filament form is not essential. For example a heating element for use as an HRG can be made from conductors used having the form of ribbons, grids or meshes, and these can be pressed or cut from a sheet. The filament 300M is used here purely as an example.

While the components in use are operated in a vacuum vessel containing a controlled, near-vacuum, non-oxidizing atmosphere, air exposure of filaments cannot be prevented during system manufacture and transport. Even after the apparatus is fully commissioned and operational, occasional servicing operations will require venting operations, which re-introduce air to the environment of the components. To mitigate this contamination source in the tungsten filament HRG, see co-pending application 61/353,359 filed 10 Jun. 2010, which proposes to operate the filament for a period at a controlled temperature at or below its evaporation temperature, in a reducing (hydrogen) atmosphere. This co-pending application is incorporated by reference herein.

As in the case of the SPF metal grid 262M, suitable metals comprise tungsten and molybdenum. The example for the sake of this discussion is tungsten. Unfortunately, after contact of the filament 300M with oxygen gas (or other oxidants), a thin layer of metal oxide, in this example case tungsten oxide (WOx), will form on the surface. This WOx layer can and will evaporate when the filament is heated to operating temperature without precautions. This evaporated WOx will then deposit on surfaces nearby, including EUV mirrors and sensors, and causes reflection losses. It has been found in experiments that HRG cleaning units can induce a ˜0.7 relative reflectivity loss on EUV mirrors on first turn-on after a three month exposure to air. Such losses are significant, yet air exposure of filaments cannot be prevented during manufacture, transport and installation.

Air exposure also occurs during servicing, when the vacuum environment within an apparatus SO, IL or PS is vented. Shortening vent times will allow less oxidation, but even 1 hour vent actions can cause unacceptable tungsten deposition on EUV mirrors.

Accordingly it is proposed to add a thin coating to the filament 300M or to modify the surface of the filament in such a way that the formation of volatile oxides is prevented. When these oxides are not formed, they cannot desorb. The coating should be able to withstand both the operating temperature and the hydrogen atmosphere in the EUV apparatus.

FIG. 9 shows HRG 300 modified with a coating 300P applied to or formed on the surface of filament 300M. Considerations as to the selection of coating material and the processes by which it can be applied or formed are the same as those discussed in relation to the coating 262P on the spectral purity filter grid 262F of FIGS. 6 and 7. It will be understood that the apparatus of FIGS. 1 to 4 incorporating metal components such as a spectral purity filter and/or HRG filament with anti-oxidation coating may be used in a lithographic manufacturing process. Such lithographic apparatus may be used in the manufacture of ICs, integrated optical systems, guidance and detection patterns for magnetic domain memories, flat-panel displays, liquid crystal displays (LCDs), thin-film magnetic heads, etc. It should be appreciated that, in the context of such alternative applications, any use of the term “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The descriptions above are intended to be illustrative, not limiting. Thus, it should be appreciated that modifications may be made to the present invention as described without departing from the scope of the claims set out below.

It will be appreciated that embodiments of the invention may be used for any type of EUV source, including but not limited to a discharge produced plasma source (DPP source), or a laser produced plasma source (LPP source). However, an embodiment of the invention may be particularly suited to suppress radiation from a laser source, which typically forms part of a laser produced plasma source. This is because such a plasma source often outputs secondary radiation arising from the laser.

The spectral purity filter may be located practically anywhere in the radiation path. In an embodiment, the spectral purity filter is located in a region that receives EUV-containing radiation from the EUV radiation source and delivers the EUV radiation to a suitable downstream EUV radiation optical system, wherein the radiation from the EUV radiation source is arranged to pass through the spectral purity filter prior to entering the optical system. In an embodiment, the spectral purity filter is in the EUV radiation source. In an embodiment, the spectral purity filter is in the EUV lithographic apparatus, such as in the illumination system or in the projection system. In an embodiment, the spectral purity filter is located in a radiation path after the plasma but before the collector.

The filament HRG can be located at any or many points in the apparatus, wherever the cleaning effect of atomic hydrogen can be beneficially applied.

While metal components in the form of SPF grids and HRG filaments have been presented as specific examples where the problem of volatile oxide formation occurs, the invention is not limited to those types of components. In general, such coatings can be applied to prevent the formation of volatile oxides on any metal component that will be exposed to elevated temperatures in the operation of the EUV lithographic apparatus. The same technique can be applied to components outside the field of EUV lithographic apparatus, if desired. The definition of ‘volatile’ in this context really depends on the expected operating temperature of each individual component. The evaporation temperature of an oxide will of course depend upon the metal from which the component is made, and may be higher or lower than the tungsten oxide of the examples.

While specific embodiments of the present invention have been described above, it should be appreciated that the present invention may be practiced otherwise than as described.

1. A component, for use in an EUV lithography apparatus, comprising a metal selected from the group consisting of: Tungsten, an alloy of Tungsten, Molybdenum and an alloy of Molybdenum wherein the component is located in a near-vacuum environment and being operated at an elevated temperature relative to the environment, wherein an exposed surface of the metal has a treatment applied thereto that inhibits been treated to inhibit the formation of an oxide of the metal in air prior to operation, thereby to prevent contamination of the environment by subsequent evaporation of the oxide during operation at the elevated temperature.

2. (canceled)

3. The component of claim 1, wherein the metal has been treated by coating with a different material, the different material not forming an oxide volatile at the elevated temperature.

4. The component of claim 3 wherein the different material comprises a different metal less susceptible to oxidation, the different metal comprising a metal selected from the group consisting of: Iridium, Rhenium, Rhodium, Ruthenium and Platinum.

5. The component of claim 3, wherein the different material comprising a metal selected from the group consisting of: aluminium oxide, oxide, zirconium oxide and hafnium oxide.

6. The component of claim 3, wherein the different material comprises one selected from the group consisting of: a nitride, a carbide, diamond-like carbon and a metal silicide.

7. The component of claim 1, wherein the metal has been treated by modifying the metal at the exposed surface to form a different material.

8. The component of claim 3 wherein the different material is a nitride or a carbide of the metal.

9. The component of claim 1, wherein the metal comprises an alloy in which at least one constituent tends to segregate at the surface, thereby to change the composition of the metal at the exposed surface.

10. The component of claim 9 wherein the constituent is a different metal less susceptible to oxidation, the different metal comprising a metal selected from the group consisting of: iridium, Rhenium, Rhodium, Ruthenium and Platinum.

11. The component of claim 9 Wherein the constituent is a different metal whose oxide is less susceptible to evaporation selected from the group consisting of: aluminium, zirconium oxide and hafnium.

12. The component of claim 1 having the form of a spectral purity filter configured to transmit extreme ultraviolet radiation, the spectral purity filter comprising a filter part having a plurality of apertures to transmit extreme ultraviolet radiation and to suppress transmission of a second type of radiation, the filter part being fabricated in the metal or fabricated in a carrier material and coated at least partially with the metal.

13. The component of claim 12 having the form of a heating element for heating gaseous molecules in the environment for the generation of an atomic gas.

14. A lithographic apparatus comprising:
a radiation source configured to generate radiation comprising extreme ultraviolet radiation;
a illumination system configured to condition the radiation into a beam of radiation;
a support configured to support a patterning device, the patterning device being configured to pattern the beam of radiation; and
a projection system configured to project a patterned beam of radiation onto a target material;
wherein at least one of said radiation source, said illumination system and said projection system is housed in a near-vacuum environment with a component comprising a metal selected from the group consisting of: Tungsten, an alloy of Tungsten, Molybdenum and an alloy of Molybdenum, wherein in use the component is located in a near-vacuum environment and being operated at an elevated temperature relative to the environment, wherein an exposed surface of the metal has a treatment applied thereto that inhibits been treated to inhibit the formation of an oxide of the metal in air prior to operation, thereby to prevent contamination of the environment by subsequent evaporation of the oxide during operation at the elevated temperature.

15. A method of manufacturing a metal component for use in EUV lithographic apparatus, the method comprising:
forming the component at least partly of a metal; and
treating an exposed surface of the metal to inhibit the formation of an oxide of the metal in an air environment prior to operation.
